(19) United States
(12) Patent Application Publication
(10) Pub. No.: US 2009/0284919 A1
(43) Pub. Date: Nov. 19, 2009

(54) HOT-PLUGGING FAN MODULE AND HOT-PLUGGING FAN SUITE

(76) Inventors: Lang Tao, Shenzhen (CN); Jun Lin, Shenzhen (CN)

Correspondence Address: BRINKS HOFER GILSON & LIONE, P.O. BOX 10395, CHICAGO, IL, 60610, US

(21) Appl. No.: 12/417,422

(22) Filed: Apr. 2, 2009

(30) Foreign Application Priority Data
May 14, 2008 (CN) 200810094736.4

(51) Int. Cl. H05K 7/20

(52) U.S. Cl. 361/695

(57) ABSTRACT

The present disclosure discloses a hot-plugging fan module, which includes a fan, a fan holder for holding the fan, and a transit circuit board module. A flexible conductive metal fin is set on one side of the transit circuit board module, and the flexible conductive metal fin is connected with a cable led out of the fan through the opposite side of the transit circuit board module. The present disclosure also discloses a hot-plugging fan suite. The embodiments of the present disclosure save space and enhance the heat dissipation capability of the system.

### CROSS-REFERENCE TO RELATED APPLICATIONS

This application claims the priority benefit of Chinese Patent Application No. 200810094736.4, filed on May 14, 2008. The contents of the above identified application are incorporated herein by reference in their entirety.

### FIELD OF THE INVENTION

The present disclosure relates to the field of communication technologies, and in particular, to a hot-plugging fan module and a hot-plugging fan suite.

### BACKGROUND

The hot-plugging technology means that the user can unplug and replace system components such as a faulty hard disk, a fan, a power supply, or a card without shutting down the system or cutting off the power supply. The hot-plugging technology thus reduces the system recovery time from disasters, and improves the scalability and flexibility of the system. For example, some disk mirroring systems oriented to high-end applications enable disks to be hot pluggable.

Currently, many hot-plugging modules exist in the industry, including stand-alone hot-plugging fan modules and integral hot-plugging fan frame modules. With the boom of blade servers, people require higher and higher density of blades, and require more and more Input & Output (I/O) modules, which gives rise to smaller and smaller space for dissipating heat. However, the increasing power consumption of processors requires higher and higher capability of heat dissipation of the system. Therefore, a limited space must hold bigger fans in order to improve the heat dissipation capability of the system.

FIG. 1 shows the structure of a fan frame for dissipating heat of a system in the prior art, where a stand-alone hot-plugging fan module 110 is installed in the system dissipation fan frame 100. FIG. 2 shows the structure of the hot-plugging fan module shown in FIG. 1. The fan module includes: a fan 111, a fan holder 112, and a fan terminal 113.

Although the hot-plugging fan module in the prior art enables the stand-alone fan module to be hot pluggable and replaceable, the whole fan module occupies a huge space because the fan terminal of the fan structure in the prior art protrudes the fan and a corresponding terminal needs to be set on the board for interconnecting with the fan terminal. Moreover, the heat dissipation capability of the system is deteriorated seriously when the module is applied inside a blade frame.

### SUMMARY

The embodiments of the disclosure provide a hot-plugging fan module and a hot-plugging fan suite to save space and enhance the heat dissipation capability of the system.

The embodiment of the disclosure discloses a hot-plugging fan module, which includes a fan, a fan holder for holding the fan, and a transit circuit board module having a first side and a second side. A flexible conductive metal fin is set on the first side of the transit circuit board module, and the flexible conductive metal fin is connected with a cable led out of the fan through the second side of the transit circuit board module.

The embodiment of the disclosure also provides a hot-plugging fan suite, which includes a plurality of hot-plugging fan modules and a fan frame for holding the plurality of hot-plugging fan modules. Each of the plurality of hot-plugging fan module includes a fan, a fan holder for holding the fan, and a transit circuit board module having a first side and a second side. A flexible conductive metal fin is set on the first side of the transit circuit board module, and the flexible conductive metal fin is connected with a cable led out of the fan through the second side of the transit circuit board module.

A transit circuit board module is applied in an embodiment of the present disclosure. Through the flexible conductive metal fin on the transit circuit board module, the module contacts the conductive metal layer on the fan frame board properly, thus fulfilling fan connection. The transit circuit board module is connected with the cable led out of the fan in the hot-plugging fan module, thus saving the space greatly, enhancing the heat dissipation capability of the system and cutting back costs.

### BRIEF DESCRIPTION OF THE DRAWINGS

FIG. 1 shows the structure of a fan frame for system heat dissipation in the prior art;

FIG. 2 shows the structure of the hot-plugging fan module shown in FIG. 1; and

FIG. 3 shows the structure of a hot-plugging fan module in the first embodiment of the present disclosure.

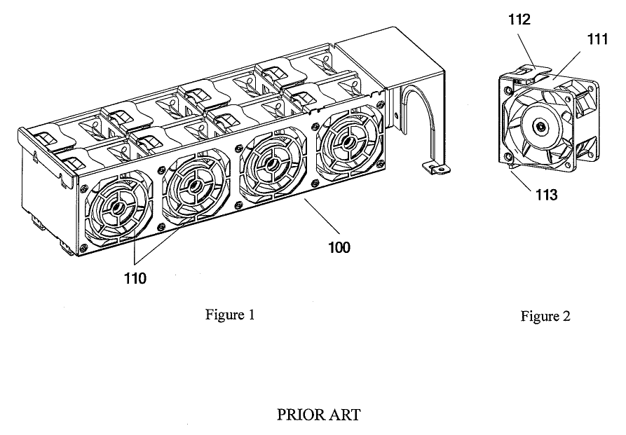

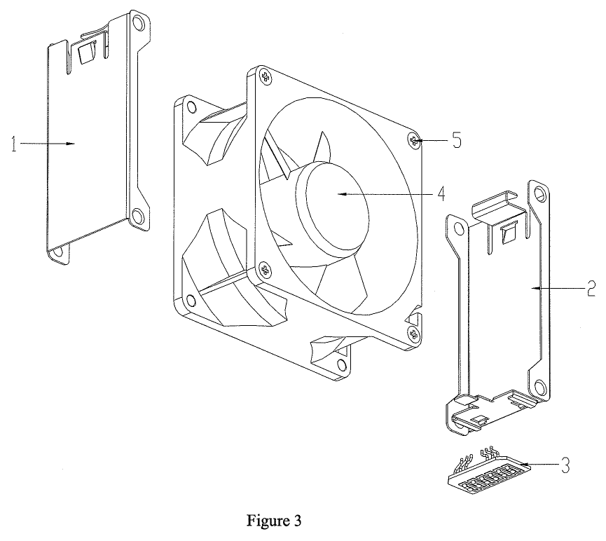

### DETAILED DESCRIPTION

The embodiment of the present disclosure provides a hot-plugging fan module and a hot-plugging fan suite to save space and improve heat dissipation of the system. The embodiments of the present disclosure are hereinafter described in detail with reference to accompanying drawings and preferred embodiments.

As shown in FIG. 3, the hot-plugging fan module in the first embodiment of the present disclosure includes: a left fan holder 1, a right fan holder 2, a transit circuit board module 3, a fan 4, and a screw 5.

The left fan holder 1 and the right fan holder 2 are fixed together with the fan 4 through the screw 5, thus forming a hot-plugging fan module. The transit circuit board module 3 is fixed to the structure below the right fan holder 2. Preferably, the transit circuit board module 3 is inserted into the slot below the right fan holder 2. Nevertheless, the transit circuit board module 3 may also be fixed to the right fan holder 2 by other means, which are not restricted by the embodiments of the present disclosure.

A flexible conductive metal fin, such as a copper fin, is set on a first side of the transit circuit board module 3, and the flexible conductive metal fin is connected with a cable led out of the fan through a second side of the transit circuit board module 3.

The transit circuit board module 3 may be in a shape suitable for being fixed onto the fan holder. However, the present disclosure does not restrict the specific shape of the transit circuit board module 3.

Preferably, the transit circuit board module 3 is a printed circuit board.

When there are two fan holders but only one transit circuit board module, the transmit circuit board module may be fixed onto any fan holder, namely, fixed onto the right fan holder 2 or onto the left fan holder 1 in the foregoing embodiment.

When there are two fan holders and two transit circuit board modules, the two transit circuit board modules may be fixed onto the two fan holders separately.

In the foregoing embodiments of the present disclosure, the terminal is independent of the fan and the fan holder like the case in the prior art, and the fan structure is the same as the fan structure in the prior art. For another structure in the prior art, namely, the terminal is lead out of the fan, or in other words, the terminal is a part of the fan structure, the present disclosure provides another embodiment, which includes: a left fan holder 1, a right fan holder 2, a transit circuit board module 3, a fan 4, and a screw 5, as shown in FIG. 3.

Among them, the structure of the fan 4 is a structure without terminals, like the first embodiment of the present disclosure described above.

The left fan holder 1 and the right fan holder 2 are fixed together with the fan 4 through the screw 5, thus forming a hot-plugging fan module. The transit circuit board module 3 is fixed to the structure below the right fan holder 2. Preferably, the transit circuit board module 3 is inserted into the slot below the right fan holder 2. Nevertheless, the transit circuit board module 3 may also be fixed to the right fan holder 2 by other means, which are not restricted by the embodiments of the present disclosure.

A flexible conductive metal fin, such as a copper fin, is set on a first side of the transit circuit board module 3, and the flexible conductive metal fin is connected with a cable led out of the fan through a second side of the transit circuit board module 3. Preferably, the cable lead out of the fan, through the fan holder, is connected with the flexible conductive metal fin through the second side of the transit circuit board module 3 by welding

The transit circuit board module 3 may be in a shape suitable for being fixed onto the fan holder. However, the present disclosure does not restrict the specific shape of the transit circuit board module 3.

Preferably, the transit circuit board module 3 is a printed circuit board.

When there are two fan holders but only one transit circuit board module, the transmit circuit board module may be fixed onto any fan holder, namely, fixed onto the right fan holder 2 or onto the left fan holder 1 in the foregoing embodiment.

When there are two fan holders and two transit circuit board modules, the two transit circuit board modules may be fixed onto the two fan holders separately.

The design of fan terminals in the prior art is omitted in the embodiments of the present disclosure, and accordingly, the terminal structure on the fan frame board is also omitted. Instead, a transit circuit board module is applied. Through the flexible conductive metal fin on the transit circuit board module, the module contacts the conductive metal layer on the fan frame board properly, thus fulfilling fan connection. The transit circuit board module is connected with the cable led out of the fan in the hot-plugging fan module through welding, thus saving the space greatly, enhancing the heat dissipation capability of the system and cutting back costs.

A transit circuit board module in the second embodiment of the present disclosure includes: a flexible conductive metal fin set on a first side of the transit circuit board module. For the structure of the metal fin, refer to the structure of the transit circuit board module 3 in FIG. 3. Preferably, the conductive metal is copper.

Preferably, the transit circuit board module is a printed circuit board.

A hot-plugging fan suite provided in the third embodiment of the present disclosure includes several hot-plugging fan modules and a fan frame for holding the hot-plugging fan module.

The hot-plugging fan module may be in a structure shown in FIG. 3, including: a fan 4, a left fan holder 1, a right fan holder 2 for holding the fan 4, and a transit circuit board module 3. A flexible conductive metal fin is set on a first side of the transit circuit board module 3. Preferably, the metal fin is a copper fin. The flexible conductive metal fin is connected with a cable led out of the fan through a second side of the transit circuit board module 3. Preferably, the cable lead out of the fan is connected with the transit circuit board module 3 through the fan holder by welding.

A conductive metal layer (which is preferably a copper layer) is set for the circuit board of the fan frame. When the hot-plugging fan module is set in the fan frame, the hot-plugging fan module is fixed onto the fan frame through the hook which protrudes out of the left fan holder 1 and the right fan holder 2. The conductive metal layer coated on the circuit board of the fan frame contacts the conductive metal fin on the hot-plugging fan module, thus fulfilling fan connection.

When there are two fan holders and one transit circuit board module, the two transit circuit board modules may be fixed onto either fan holder.

When there are two fan holders and two transit circuit board modules, the two transit circuit board modules are fixed onto the two fan holders separately.

The present disclosure provides a hot-plugging fan module and a hot-plugging fan suite; the design of fan terminals in the prior art is omitted in the embodiments of the present disclosure, and accordingly, the terminal structure on the fan frame board is also omitted. Instead, a transit circuit board module is applied. Through the flexible conductive metal fin on the transit circuit board module, the module contacts the conductive metal layer on the fan frame board properly, thus fulfilling fan connection. The transit circuit board module is connected with the cable led out of the fan in the hot-plugging fan module through welding, thus saving the space greatly, enhancing the heat dissipation capability of the system and cutting back costs.

Although the disclosure has been described through some exemplary embodiments, the disclosure is not limited to such embodiments. It is apparent that those skilled in the art can make various modifications and variations to the disclosure without departing from scope of the disclosure.

What is claimed is:

1. A hot-plugging fan module, comprising:
a fan;
a fan holder for holding the fan; and
a transit circuit board module having a first side and a second side,
wherein a flexible conductive metal fin is set on the first side of the transit circuit board module, and the flexible conductive metal fin is connected with a cable led out of the fan through the second side of the transit circuit board module.

2. The hot-plugging fan module according to claim 1, wherein the flexible conductive metal fin is a copper fin.

3. The hot-plugging fan module according to claim 1, wherein the hot-plugging fan module has a plurality of fan holders and one transit circuit board module, the transit circuit board module is connected with one of the plurality of fan holders.

4. The hot-plugging fan module according to claim 1, wherein the hot-plugging fan module has a plurality of fan holders and a plurality of transit circuit board modules, each of the plurality of transit circuit board modules is connected with each of the plurality of fan holders individually.

5. The hot-plugging fan module according to claim 1, wherein the cable, through the fan holder, is connected with the flexible conductive metal fin through the second side of the transit circuit board module by welding.

6. A hot-plugging fan suite, comprising:
a plurality of hot-plugging fan modules;
a fan frame for holding the plurality of hot-plugging fan modules;
wherein each of the plurality of hot-plugging fan module comprising:
a fan;
a fan holder for holding the fan; and
a transit circuit board module having a first side and a second side,
wherein a flexible conductive metal fin is set on the first side of the transit circuit board module, and the flexible conductive metal fin is connected with a cable led out of the fan through the second side of the transit circuit board module.

7. The hot-plugging fan suite according to claim 6, wherein the flexible conductive metal fin is a copper fin.

8. The hot-plugging fan suite according to claim 6, wherein each of the plurality of hot-plugging fan modules has a plurality of fan holders and one transit circuit board module, the transit circuit board module is connected with one of the plurality of the fan holders.

9. The hot-plugging fan suite according to claim 6, wherein each of the plurality of hot-plugging fan modules has a plurality of fan holders and a plurality of transit circuit board modules, each of the plurality of transit circuit board modules is connected with each of the plurality of fan holders individually.

10. The hot-plugging fan suite according to claim 6, wherein the cable, through the fan holder, is connected with the flexible conductive metal fin through the second side of the transit circuit board module by welding.

11. The hot-plugging fan suite according to claim 6, wherein the hot-plugging fan module is installed in the fan frame, the flexible conductive metal fin is connected to a conductive metal layer which is set on the circuit board of the fan frame.

12. The hot-plugging fan suite according to claim 11, wherein the flexible conductive metal fin is a copper fin.

13. The hot-plugging fan suite according to claim 11, wherein each of the plurality of hot-plugging fan modules has a plurality of fan holders and one transit circuit board module, the transit circuit board module is connected with one of the plurality of the fan holders.

14. The hot-plugging fan suite according to claim 11, wherein each of the plurality of hot-plugging fan modules has a plurality of fan holders and a plurality of transit circuit board modules, each of the plurality of transit circuit board modules is connected with each of the plurality of fan holders individually.

15. The hot-plugging fan suite according to claim 11, wherein the cable, through the fan holder, is connected with the flexible conductive metal fin through the second side of the transit circuit board module by welding.
